(19) United States
(12) Patent Application Publication
(10) Pub. No.: US 2011/0205793 A1
(43) Pub. Date: Aug. 25, 2011

(54) METHOD FOR ACCESSING MULTI-LEVEL NON-VOLATILE MEMORY CELL

(76) Inventor: Hsiao-Ming Huang, Kao-Hsiung City (TW)

(21) Appl. No.: 12/712,184

(22) Filed: Feb. 24, 2010

(51) Int. Cl. G11C 16/04

(52) U.S. Cl. 365/185.03

(57) ABSTRACT

A method for accessing a multi-level non-volatile memory cell includes the following steps: determining at least one target word line voltage according to a target bit to be read from a plurality of bits stored in the multi-level non-volatile memory cell; and applying the at least one target word line voltage to the multi-level non-volatile memory cell in order to determine the target bit. Herein the at least one target word line voltage includes at most 2^{(N-1)} word line voltages, where N is a total number of the plurality of bits stored in the multi-level non-volatile memory cell.

### BACKGROUND OF THE INVENTION

1. Field of the Invention

The present invention relates to accessing one or a plurality of multi-level non-volatile memory (NVM) cells, and more particularly, to a method for determining a plurality of target bits respectively corresponding to multi-level non-volatile memory cells in one read operation by taking one bit stored in each multi-level non-volatile memory cell as a read-out unit.

2. Description of the Prior Art

A semiconductor memory can be divided into two categories: volatile memories and non-volatile memories. For example, a dynamic random access memory (DRAM) is a volatile memory, and a flash memory is a non-volatile memory. The difference between these categories is whether the stored data can be reserved for a long time when external electric power is turned off. In a case where the external electric power is turned off, the data stored in the volatile memory will disappear, but the data stored in the non-volatile memory will be preserved.

Nowadays, the non-volatile memories have been widely employed in a variety of applications. Please refer to FIG. 1 together with FIG. 2 and FIG. 3. FIG. 1 is a diagram showing a conventional multi-level non-volatile memory cell 100, and FIG. 2 and FIG. 3 are diagrams illustrating how to access the conventional multi-level non-volatile memory cell 100 according to the prior art. As shown in FIG. 1, the multi-level non-volatile memory cell 100 is simply implemented by a transistor Q1 with a floating gate FG. Herein the transistor Q1 has a first end N1 coupled to a bit line BL, a second end N2 coupled to a ground, and a control end NC coupled to a word line WL. The transistor Q1 can be programmed or erased to control electrons accumulated on the floating gate FG. In this way, a threshold voltage Vt of the transistor Q1 can be configured to fall within one of a plurality of predetermined voltage ranges. Be noted that when a word line voltage V(WL) applied to the control node NC of the transistor Q1 is greater than the threshold voltage Vt, the transistor Q1 is turned on; and when the word line voltage V(WL) is smaller than the threshold voltage Vt, the transistor Q1 is turned off.

As shown in FIG. 2, assuming that the multi-level non-volatile memory cell 100 is used for storing a data with two bits Bit[1:0], these two bits Bit[1:0] can be represented by one of four possible threshold voltage levels, namely: Level 0 (00), Level 1 (01), Level 2 (10), and Level 3 (11) in an increasing order of threshold voltage levels. In this example, three target word line voltages S0, S1, and S2 may be used for reading the content of the bits Bit[1:0] stored in the multi-level non-volatile memory cell 100. In other words, when the threshold voltage Vt is found smaller than the target word line voltage S0, it implies that the bits Bit [1:0] correspond to Level 0 (00); when the threshold voltage Vt is found in between the target word line voltages S0 and S1, it implies that the bits Bit[1:0] correspond to Level 1 (01); when the threshold voltage Vt is found in between the applied target word line voltages S1 and S2, it implies that the bits Bit[1:0] correspond to Level 2 (10); and when the threshold voltage Vt is found greater than the target word line voltage S2, it implies that the bits Bit[1:0] correspond to Level 3 (11). Therefore, when a voltage level at the bit line BL is pulled down due to the electrically conductive transistor Q1, it means that the currently applied word line voltage V(WL) is greater than the threshold voltage Vt of the transistor Q1. Hence, by testing the word line voltages S0, S1, and S2 one by one, the bits Bit[1:0] which are stored in the transistor Q1 (i.e., the multi-level non-volatile memory cell 100) by setting the threshold voltage Vt can be known.

As shown in FIG. 3, the bit line BL is pre-charged to a preset voltage level first. After that, the three target word line voltages S0, S1, and S2 are sequentially applied to the word line WL as the word line voltage V(WL). If the word line voltage V(WL) is greater than the threshold voltage Vt, the transistor Q1 will be turned on to discharge the bit line BL, thereby pulling down the voltage level at the bit line BL. As an illustration, if the transistor Q1 shown in FIG. 1 is erased to have the threshold voltage Vt corresponding to Level 0 (i.e., the lowest threshold voltage), the transistor Q1 will be turned on when the target word line voltage S0 is applied to the word line WL. As another illustration, if the transistor Q1 is programmed to have the threshold voltage Vt corresponding to Level 1, the transistor Q1 will be turned on when the target word line voltage S1 following the target word line voltage S0 is applied to the word line WL. As yet another illustration, if the transistor Q1 is programmed to have the threshold voltage Vt corresponding to Level 2, the transistor Q1 will be turned on when the target word line voltage S2 following the target word line voltage S1 is applied to the word line WL. If the target word line voltages S0, S1, and S2 fail to turn on the transistor Q1, the voltage level at the bit line BL is kept at the preset voltage level, implying that the transistor Q1 shown in FIG. 1 is programmed to have the threshold voltage Vt corresponding to Level 3 (i.e., the highest threshold voltage). As shown in FIG. 3, the word line WL and the bit line BL will be reset after the target word line voltages S0, S1, and S2 have been sequentially used as the word line voltage V(WL).

As can be seen from FIG. 2 and FIG. 3, by adopting the conventional access method to access the multi-level non-volatile memory cell 100, three read iterations are required to get a data with two bits in one read operation, and its access efficiency is equal to 2/3=0.67. That is to say, (2^{N}−1) read iterations are required to get a data with N bits in one read operation, and its access efficiency is equal to

$$( \frac{N}{{2}^{N} - 1} ) .$$

By adopting the conventional access method to access the multi-level non-volatile memory cell 100, the access efficiency gets worse as the total number N of the bits stored in the multi-level non-volatile memory cell 100 increases.

### SUMMARY OF THE INVENTION

It is one of the objectives of the present invention to provide a method for accessing one or a plurality of multi-level non-volatile memory cells to solve the abovementioned problems.

According to one aspect of the present invention, an exemplary method for accessing a multi-level non-volatile memory cell is provided. The exemplary method includes the following steps: determining at least one target word line voltage according to a target bit to be read from a plurality of bits stored in the multi-level non-volatile memory cell; and applying the at least one target word line voltage to the multi-level non-volatile memory cell in order to determine the target bit. Herein the at least one target word line voltage includes at most 2^{(N-1)} word line voltages, where N is a total number of the plurality of bits stored in the multi-level non-volatile memory cell.

According to another aspect of the present invention, an exemplary method for accessing a plurality of multi-level non-volatile memory cells is provided. The exemplary method includes the following steps: determining at least one first target word line voltage according to a first target bit to be read from a plurality of bits stored in each of the multi-level non-volatile memory cells; applying the at least one first target word line voltage to the multi-level non-volatile memory cells in order to determine a plurality of first target bits respectively corresponding to the multi-level non-volatile memory cells, wherein each of the plurality of first target bits has an identical first bit position; determining at least one second target word line voltage according to a second target bit to be read from the plurality of bits stored in each of the multi-level non-volatile memory cells; and applying the at least one second target word line voltage to the multi-level non-volatile memory cells in order to determine a plurality of second target bits respectively corresponding to the multi-level non-volatile memory cells, wherein each of the plurality of second target bits has an identical second bit position different from the first bit position.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram showing a conventional multi-level non-volatile memory cell.

FIG. 2 is a diagram illustrating a relation between word line voltages and bits stored in a conventional multi-level non-volatile memory cell.

FIG. 3 is a timing diagram illustrating how a conventional access method accesses a multi-level non-volatile memory cell.

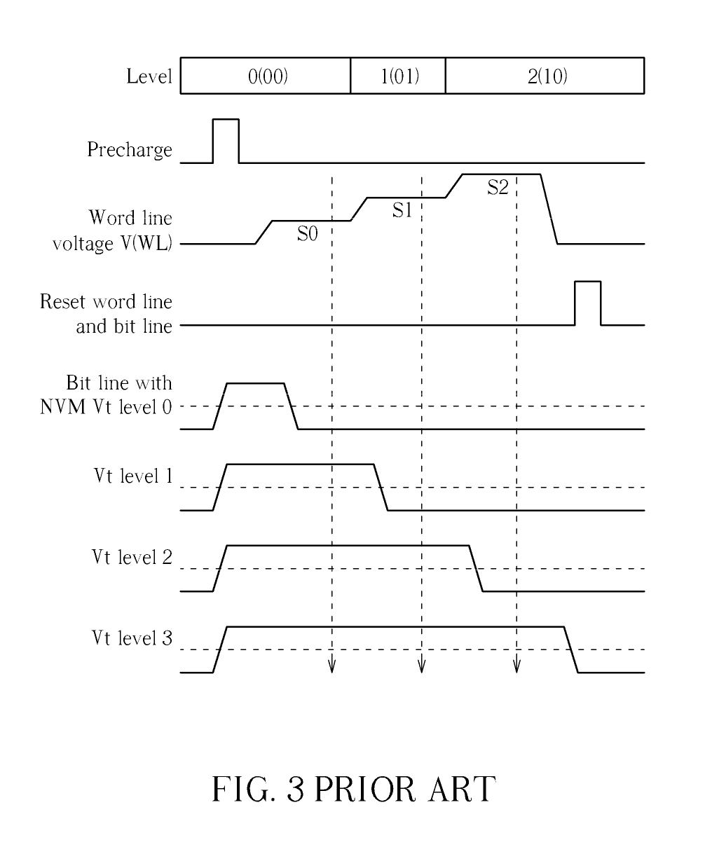

FIG. 4 is a flowchart illustrating a method for accessing a multi-level non-volatile memory cell according to an exemplary embodiment of the present invention.

FIG. 5 is a diagram illustrating an exemplary relation between word line voltages and bits stored in a multi-level non-volatile memory cell according to the present invention.

FIG. 6 is a diagram illustrating how an exemplary access method of the present invention accesses a multi-level non-volatile memory cell.

FIG. 7 is a diagram illustrating another exemplary relation between word line voltages and bits stored in a multi-level non-volatile memory cell according to the present invention.

FIG. 8 is a flowchart illustrating a method for accessing a plurality of multi-level non-volatile memory cells according to another exemplary embodiment of the present invention.

### DETAILED DESCRIPTION

Certain terms are used throughout the following description and claims to refer to particular components. As one skilled in the art will appreciate, hardware manufacturers may refer to a component by different names. This document does not intend to distinguish between components that differ in name but in function. In the following discussion and in the claims, the terms “include”, “including”, “comprise”, and “comprising” are used in an open-ended fashion, and thus should be interpreted to mean “including, but not limited to . . . ”. The terms “couple” and “coupled” are intended to mean either an indirect or a direct electrical connection. Thus, if a first device couples to a second device, that connection may be through a direct electrical connection, or through an indirect electrical connection via other devices and connections.

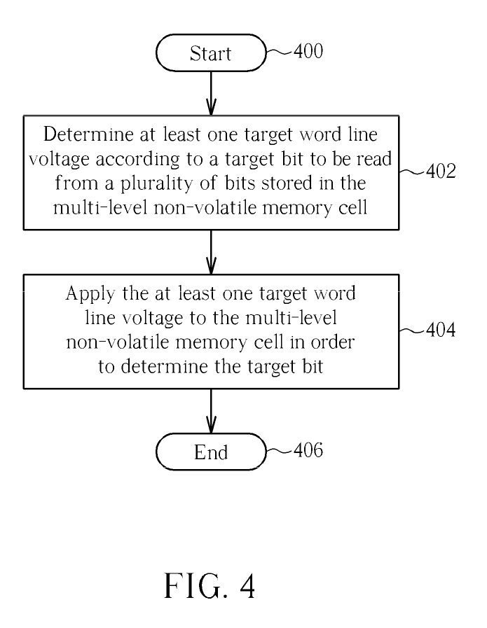

Please refer to FIG. 4, which is a flowchart illustrating a method for accessing a multi-level non-volatile memory cell according to an exemplary embodiment of the present invention. Provided that the result is substantially the same, the steps are not required to be executed in the exact order shown in FIG. 4. The exemplary method includes, but is not limited to, the following steps:

Step 400: Start.

Step 402: Determine at least one target word line voltage according to a target bit to be read from a plurality of bits stored in the multi-level non-volatile memory cell.

Step 404: Apply the at least one target word line voltage to the multi-level non-volatile memory cell in order to determine the target bit.

Step 406: End.

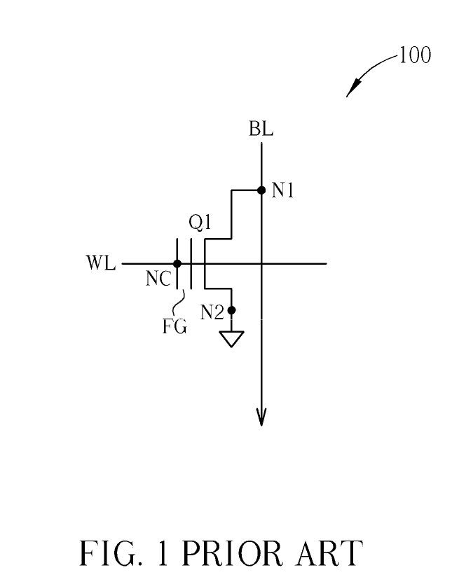

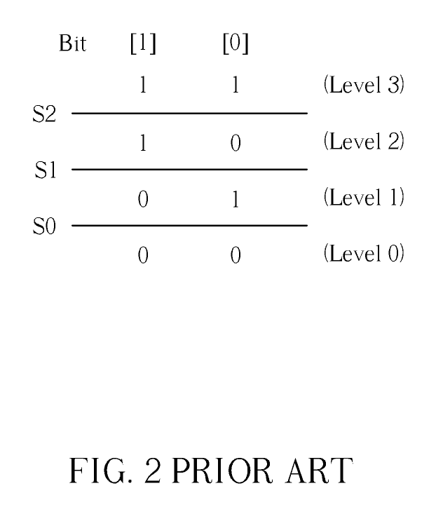

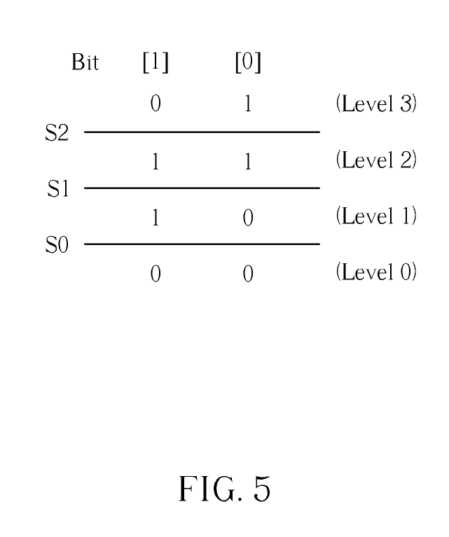

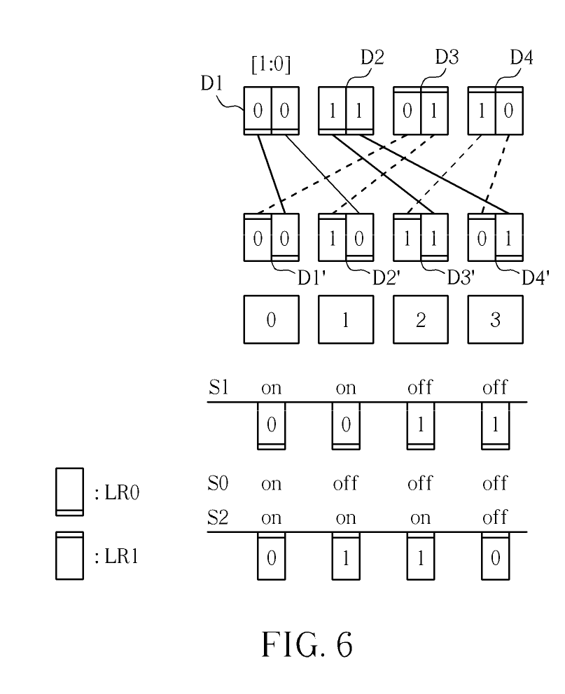

Please refer to FIG. 1 and FIG. 4, together with FIG. 5 and FIG. 6. FIG. 5 and FIG. 6 are diagrams illustrating how to access a multi-level non-volatile memory cell (e.g., the multi-level non-volatile memory cell 100 shown in FIG. 1) according to a first embodiment of the present invention. Continuing with the example mentioned above, in FIG. 5, provided that the multi-level non-volatile memory cell 100 is used for storing a data with two bits Bit[1:0], these two bits Bit[1:0] can be represented by one of four possible threshold voltage levels, namely: Level 0 (00), Level 1 (10), Level 2 (11), and Level 3 (01) in an increase order of threshold voltage levels. In this embodiment, the mapping between the threshold voltage levels and the stored bits is different from that shown in FIG. 2. More specifically, if the transistor Q1 is erased to have the threshold voltage Vt corresponding to Level 0 for storing bits Bit[1:0]=00, the transistor Q1 will be turned on when the target word line voltage S0 is applied to the word line WL; if the transistor Q1 is programmed to have the threshold voltage Vt corresponding to Level 1 for storing bits Bit[1:0]=10, the transistor Q1 will be turned on when the target word line voltage S1 is applied to the word line WL; if the transistor Q1 is programmed to have the threshold voltage Vt corresponding to Level 2 for storing bits Bit[1:0]=11, the transistor Q1 will be turned on when the target word line voltage S2 is applied to the word line WL; and if the transistor Q1 is programmed to have the threshold voltage Vt corresponding to Level 3 for storing bits Bit[1:0]=01, none of the target word line voltages S0, S1, and S2 can turn on the transistor Q1.

Based on the above observation, one target word line voltage S1 can be used for reading (identifying) the content of the first bit Bit[0] (i.e., the Least Significant Bit, LSB), and two target word line voltages S0 and S2 are used for reading (identifying) the content of the second bit Bit[1] (i.e., the Most Significant Bit, MSB). The read operation of a target bit, either the first bit Bit[0] or the second bit Bit[1], is executed by Step 402 and Step 404 in FIG. 4. For example, when the threshold voltage Vt of the transistor Q1 is smaller than the target word line voltage S1, it represents that the first bit Bit[0] corresponds to a logic value “0”; when the threshold voltage Vt is greater than the target word line voltage S1, it represents that the first bit Bit[0] corresponds to a logic value “1”. Similarly, with regard to reading the second bit Bit[1], when the threshold voltage Vt is smaller than the target word line voltage S0 or greater than the target word line voltage S2, it represents that the second bit Bit[1] corresponds to the logic value “0”; in addition, when the threshold voltage Vt is in between the target word line voltages S0 and S2, it represents that the second bit Bit[1] corresponds to the logic value “1”.

As shown in FIG. 6, in this embodiment, an input data having a first bit sequence of (00)→(11)→(01)→(10) is first re-arranged to generate a re-arranged data with a second bit sequence of (00)→(10)→(11)→(01). In other words, the second bit Bit[1] and the first bit Bit[0] of the partial data D1 are re-arranged as the first bit Bit[0] of the partial data D1′ and the first bit Bit[0] of the partial data D2′, respectively; the second bit Bit[1] and the first bit Bit[0] of the partial data D2 are re-arranged as the first bit Bit[0] of the partial data D3′ and the first bit Bit[0] of the partial data D4′, respectively; the second bit Bit[1] and the first bit Bit[0] of the partial data D3 are re-arranged as the second bit Bit[1] of the partial data D1′ and the second bit Bit[1] of the partial data D2′, respectively; the second bit Bit[1] and the first bit Bit[0] of the partial data D4 are re-arranged as the second bit Bit[1] of the partial data D3′ and the second bit Bit[1] of the partial data D4′, respectively. In a conventional design, a first multi-level non-volatile memory cell is erased to have a threshold voltage Vt corresponding to Level 0 for storing the partial data D1 (00), a second multi-level non-volatile memory cell is programmed to have a threshold voltage Vt corresponding to Level 3 for storing the partial data D2 (11), a third multi-level non-volatile memory cell is programmed to have a threshold voltage Vt corresponding to Level 1 for storing the partial data D3 (01), and a fourth multi-level non-volatile memory cell is programmed to have a threshold voltage Vt corresponding to Level 3 for storing the partial data D4 (10). As mentioned above, three read iterations are required to get two bits of each partial data stored in one multi-level non-volatile memory cell. However, in contrast to the conventional design, an exemplary design of the present invention employs the new mapping between threshold voltage levels and bits to be stored in the multi-level non-volatile memory cell as shown in FIG. 5 to make the first multi-level non-volatile memory cell erased to have a threshold voltage Vt corresponding to Level 0 for storing the partial data D1′ (00), the second multi-level non-volatile memory cell programmed to have a threshold voltage Vt corresponding to Level 1 for storing the partial data D2′ (10), the third multi-level non-volatile memory cell programmed to have a threshold voltage Vt corresponding to Level 2 for storing the partial data D3′ (11), and the fourth multi-level non-volatile memory cell programmed to have a threshold voltage Vt corresponding to Level 3 for storing the partial data D4′ (01). It should be noted that first bits of the partial data D1′, D2′, D3′ and D4′ of the re-arranged data are viewed as data of a first logical region LR0, and second bits of the partial data D1′, D2′, D3′ and D4′ of the re-arranged data are viewed as data of a second logical region LR1. Specifically, in one exemplary implementation of the present invention, the number of logical regions will be equal to the number of bits stored in the multi-level non-volatile memory cell 100.

With regard to reading data of the first logical region LR0 (i.e., bits of the partial data D1 and bits of the partial data D2), only one voltage 51 is applied to the word line WL as the target word line voltage. As a result, the output data of the first logical region LR0 read from four multi-level non-volatile memory cells is determined as 0, 0, 1, 1. With regard to reading data of the second logical region LR1 (i.e., bits of the partial data D3 and bits of the partial data D4), the voltages S0 and S2 are sequentially applied to the word line WL as the target word line voltages, respectively. As a result, the output data of the second logical region LR1 read from four multi-level non-volatile memory cells is determined as 0, 1, 1, 0.

As can be seen from FIG. 5 and FIG. 6, by adopting the exemplary access method disclosed in the present invention to access a multi-level non-volatile memory (e.g., the multi-level non-volatile memory cell 100 shown in FIG. 1), only one read iteration is required to get the output data of the first logical region LR0 in one read operation and two read iterations are required to get the output data of the second logical region LR1 in another read operation. Provided that the chance to read each logical region is the same, the access efficiency is equal to

$$[ \frac{1}{2} \times ( 1 + \frac{1}{2} ) ] = \frac{3}{4} = 0.75 .$$

Compared with the access efficiency of the conventional access method as mentioned above, the access efficiency can be improved by adopting the exemplary access method disclosed in the present invention.

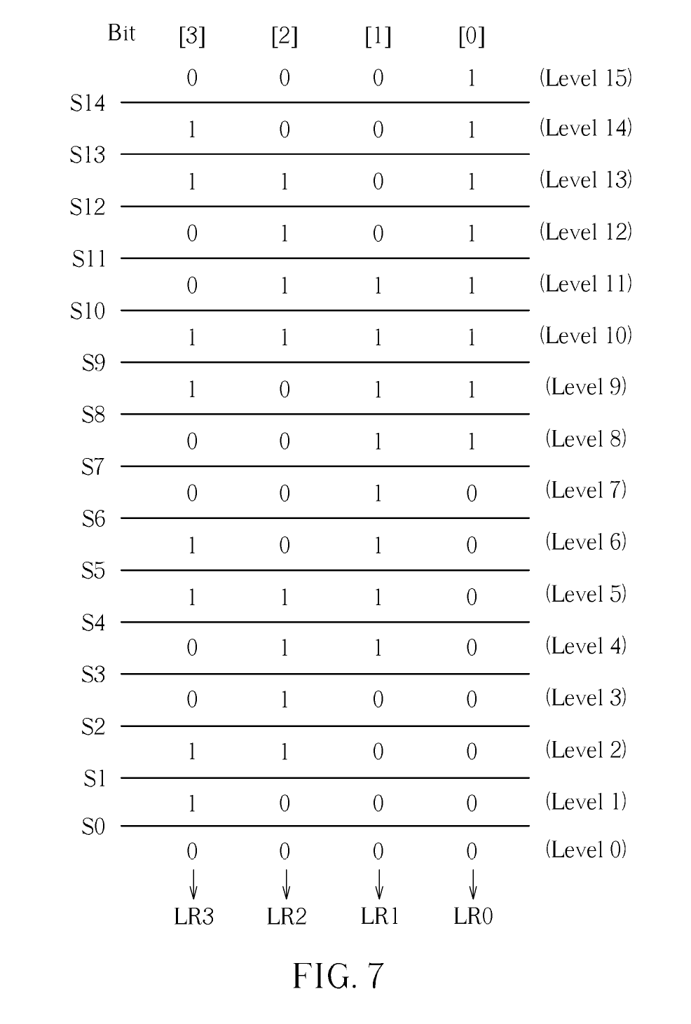

Please refer to FIG. 1 and FIG. 4, together with FIG. 7. FIG. 7 is a diagram illustrating another exemplary relation between word line voltages and bits stored in a multi-level non-volatile memory cell according to the present invention. Assume that the multi-level non-volatile memory cell 100 shown in FIG. 1 is used for storing a data with four bits Bit[3:0], and these four bits Bit[3:0] can be represented by one of sixteen possible threshold voltage levels, namely: Level 0 (0000), Level 1 (1000), Level 2 (1100), . . . , and Level 15 (0001) in an increasing order of threshold voltage levels. Herein the first bit Bit[0] stored in each multi-level non-volatile memory cell 100 belongs to a first logical region LR0, the second bit Bit[1] stored in each multi-level non-volatile memory cell 100 belongs a second logical region LR1, the third bit Bit[2] stored in each multi-level non-volatile memory cell 100 belongs a third logical region LR2, and the fourth bit Bit[3] stored in each multi-level non-volatile memory cell 100 belongs to a fourth logical region LR3. Similarly, the number of logical regions is equal to the number of bits stored in the multi-level non-volatile memory cell.

In this embodiment, only one target word line voltage S7 is used for reading the content of the first bit Bit[0] (i.e., the Least Significant Bit, LSB) of one or more multi-level non-volatile memory cells 100; two target word line voltages S3 and 511 are used for reading the content of the second bit Bit[1] of one or more multi-level non-volatile memory cells 100; four target word line voltages 51, S5, S9, and 513 are used for reading the content of the third bit Bit[0] of one or more multi-level non-volatile memory cells 100; and eight target word line voltages S0, S2, S4, S6, S8, S10, 512, and S14 are used for reading the content of the fourth bit Bit[3] (i.e., the Most Significant Bit, MSB) of one or more multi-level non-volatile memory cells 100. The read operation of each bit is also executed by Step 402 and Step 404 in FIG. 4. For example, when the threshold voltage Vt of the multi-level non-volatile memory cell 100 is smaller than the target word line voltage S7, the voltage level at the bit line BL will indicate that the first bit Bit[0] corresponds to a logic value “0”; when the threshold voltage Vt is greater than the target word line voltage S7, the voltage level at the bit line BL will indicate that the first bit Bit[0] corresponds to a logic value “1”. As a person skilled in the art can readily understand the operation of reading other bits Bit[1], Bit[2] and Bit[3] stored in the multi-level non-volatile memory cell 100 after reading above paragraphs, further description is omitted here for brevity.

In view of above, by adopting the access method disclosed in the present invention to access the multi-level non-volatile memory, one read iteration is required to get the output data of the first logical region LR0 in one read operation, two read iterations are required to get the output data of the second logical region LR1 in one read operation, four read iterations are required to get the output data of the third logical region LR2 in one read operation, and eight read iterations are required to get the output data of the fourth logical region LR4 in one read operation. Provided that the chance to read each logical region is the same, the access efficiency is equal to

$$[ \frac{1}{4} \times ( 1 + \frac{1}{2} + \frac{1}{4} + \frac{1}{8} ) ] = \frac{15}{32} = 0.46 .$$

Regarding the access efficiency of the conventional access method, fifteen read iterations are required to get a data of four bits and thus its access efficiency is equal to

$$\frac{4}{15} = 0.27 .$$

As can be seen, the access efficiency can be improved by adopting the exemplary access method disclosed in the present invention.

What calls for special attention is that: each of the target word line voltages corresponding to the bit denoted as Bit[a] is different from each of the target word line voltages corresponding to the bit denoted as Bit[b], wherein the bit denoted as Bit[a] is different from the bit denoted as Bit[b]. By way of example, but not limitation, only a single word line voltage is used for reading the content of an LSB bit, and at most 2^{(N-1)} word line voltages are used for reading the content of an MSB bit, where N is a total number of the plurality of bits stored in one multi-level non-volatile memory cell, and may be any positive integer according to an actual design of the multi-level non-volatile memory cell. But this should not be taken as a limitation of the present invention. Various modifications without departing from the spirit of the present invention are feasible.

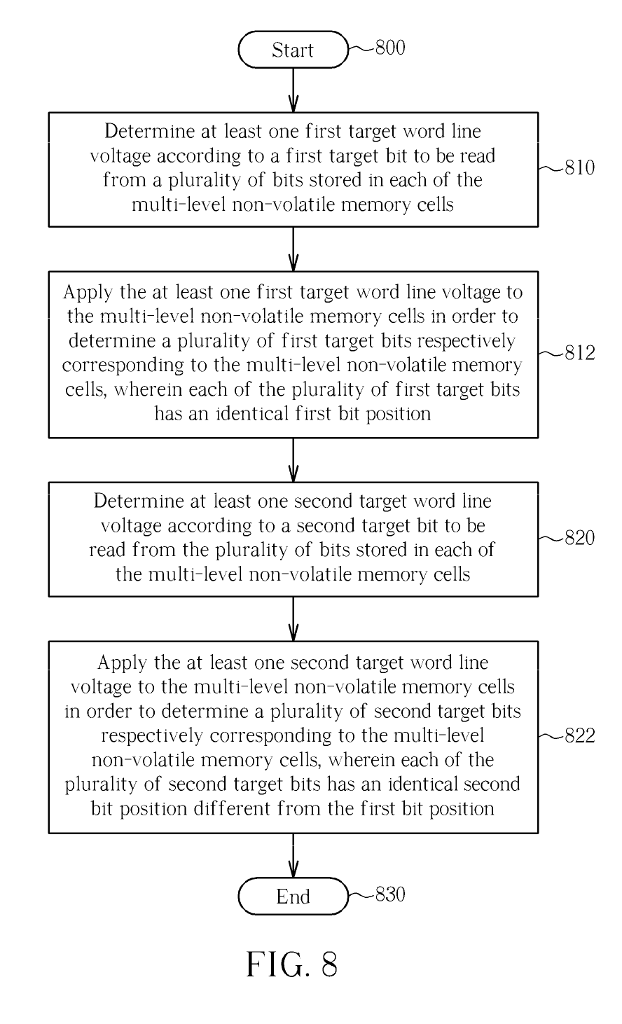

Please refer to FIG. 8. FIG. 8 is a flowchart illustrating a method for accessing a plurality of multi-level non-volatile memory cells according to another exemplary embodiment of the present invention. Provided that the result is substantially the same, the steps are not required to be executed in the exact order shown in FIG. 8. The method includes, but is not limited to, the following steps:

Step 800: Start.

Step 810: Determine at least one first target word line voltage according to a first target bit to be read from a plurality of bits stored in each of the multi-level non-volatile memory cells.

Step 812: Apply the at least one first target word line voltage to the multi-level non-volatile memory cells in order to determine a plurality of first target bits respectively corresponding to the multi-level non-volatile memory cells, wherein each of the plurality of first target bits has an identical first bit position.

Step 820: Determine at least one second target word line voltage according to a second target bit to be read from the plurality of bits stored in each of the multi-level non-volatile memory cells.

Step 822: Apply the at least one second target word line voltage to the multi-level non-volatile memory cells in order to determine a plurality of second target bits respectively corresponding to the multi-level non-volatile memory cells, wherein each of the plurality of second target bits has an identical second bit position different from the first bit position.

Step 830: End.

The steps shown in FIG. 8 are similar to the steps shown in FIG. 4, and the difference between them is that FIG. 8 focuses on accessing a plurality of multi-level non-volatile memory cells while FIG. 4 focuses on accessing one multi-level non-volatile memory cell. It should be noted that a plurality of target bits respectively corresponding to multi-level non-volatile memory cells are read in one read operation by taking one bit stored in each multi-level non-volatile memory cell as a read-out unit. By way of example, but not limitation, first target bits having the same first bit position (e.g., first bits Bit[0]) in the multi-level non-volatile memory cells are simultaneously read in one read operation which uses first target word line voltage(s), and second target bits having the same second bit position (e.g., second bits Bit[0]) in the multi-level non-volatile memory cells are simultaneously read in another read operation which uses proper second target word line voltage(s). Be noted that the first target bit to be read from the plurality of bits stored in each of the multi-level non-volatile memory cells belongs to a first logical region, and the second target bit to be read from the plurality of bits stored in each of the multi-level non-volatile memory cells belongs to a second logical region. As operations of the steps shown in FIG. 4 have been detailed in abovementioned embodiments (please refer to FIG. 4-FIG. 7), further description of the steps shown in FIG. 8 is omitted here for brevity.

Be noted that each of the first target word line voltage(s) is different from each of the second target word line voltage(s). Furthermore, a total number of the first target word line voltages is different from a total number of the second target word line voltages.

Please also note that, the steps of the abovementioned flowcharts are presented merely for describing the present invention, and in no way should be considered to be limitations of the scope of the present invention. Those skilled in the art should observe that the methods shown in FIG. 4 and FIG. 8 can include other intermediate steps or several steps can be merged into a single step without departing from the spirit of the present invention.

As shown in FIG. 6, the first bit Bit[0] stored in each multi-level non-volatile memory cell belongs to a first logical region LR0 through a re-arrangement of bits of original input data, and the second bit Bit[1] stored in each multi-level non-volatile memory cell belongs to a second logical region LR1 through a re-arrangement of bits of original input data, where the number of logical regions is equal to the number of bits stored in each multi-level non-volatile memory cell. It should be noted that the data of the first logical region LR0 can be read by using a single target word line voltage (e.g., S1), but the data of the second logical region LR1 must be read by using a plurality of target word line voltages (e.g., S0 and S2). Therefore, in order to improve the access efficiency further, bits belong to more frequently accessed data can be mapped to a logical region (e.g., LSBs stored in multi-level non-volatile memory cells) whose content can be read or identified by using a minimum number of target word line voltages (e.g., a single target word line voltage S7 shown in FIG. 7), and bits belong to less frequently accessed data can be mapped to a logical region (e.g., MSBs stored in multi-level non-volatile memory cells) whose content can be read or identified by a maximum number of target word line voltages (e.g., target word line voltages S0, S2, S4, S6, S8, S10, S12, and S14 shown in FIG. 7). Those skilled in the art should observe that various modifications of the mappings of the logical regions may be made without departing from the spirit of the present invention, which also belongs to the scope of the present invention.

Be noted that the access method for accessing a multi-level non-volatile memory cell disclosed in the present invention can be applied to a flash memory, such as a NOR flash or a NAND flash. But this should not be considered as limitations of the present invention, and the access method disclosed in the present invention can be applied to a non-volatile memory cell of other types.

The abovementioned embodiments are presented merely for describing features of the present invention, and in no way should be considered to be limitations of the scope of the present invention. In summary, the present invention provides a method for accessing multi-level non-volatile memory cell(s). By adopting the exemplary access mechanism disclosed in the present invention, the access efficiency for reading a data with N bits can be represented by

$$[ \frac{1}{N} \times ( 1 + \frac{1}{2} + \frac{1}{4} + … + \frac{1}{{2}^{N - 1}} ) ] .$$

Regarding the conventional access method, the access efficiency for reading a data with N bits is equal to

$$\frac{N}{{2}^{N} - 1} .$$

As can be seen, the access efficiency can be greatly improved by adopting the exemplary access method disclosed in the present invention. With regard to the conventional access method, all of the target word line voltages are required to get the data. Since the access mechanism disclosed in the present invention takes one bit as a unit, only one or a part of target word line voltages (at most 2^{(N-1)} word line voltages) are required to get each bit of the stored data.

Those skilled in the art will readily observe that numerous modifications and alterations of the device and method may be made while retaining the teachings of the invention.

What is claimed is:

1. A method for accessing a multi-level non-volatile memory cell, comprising the following steps:
determining at least one target word line voltage according to a target bit to be read from a plurality of bits stored in the multi-level non-volatile memory cell; and
applying the at least one target word line voltage to the multi-level non-volatile memory cell in order to determine the target bit.

2. The method of claim 1, wherein the step of determining the at least one word line voltage comprises:
when the target bit is a first bit of the plurality of bits stored in the multi-level non-volatile memory cell, selecting at least one first word line voltage as the at least one target word line voltage; and
when the target bit is a second bit of the plurality of bits stored in the multi-level non-volatile memory cell, selecting at least one second word line voltage as the at least one target word line voltage, where the second bit is different from the first bit, and each of the at least one first word line voltage is different from each of the at least one second word line voltage.

3. The method of claim 1, wherein the at least one target word line voltage includes a single word line voltage only.

4. The method of claim 1, wherein the at least one target word line voltage includes at most 2^{(N-1)} word line voltages, where N is a total number of the plurality of bits stored in the multi-level non-volatile memory cell.

5. The method of claim 1, wherein the non-volatile memory cell is a NOR flash or a NAND flash.

6. A method for accessing a plurality of multi-level non-volatile memory cells, comprising the following steps:
determining at least one first target word line voltage according to a first target bit to be read from a plurality of bits stored in each of the multi-level non-volatile memory cells;
applying the at least one first target word line voltage to the multi-level non-volatile memory cells in order to determine a plurality of first target bits respectively corresponding to the multi-level non-volatile memory cells, wherein each of the plurality of first target bits has an identical first bit position;
determining at least one second target word line voltage according to a second target bit to be read from the plurality of bits stored in each of the multi-level non-volatile memory cells; and
applying the at least one second target word line voltage to the multi-level non-volatile memory cells in order to determine a plurality of second target bits respectively corresponding to the multi-level non-volatile memory cells, wherein each of the plurality of second target bits has an identical second bit position different from the first bit position.

7. The method of claim 6, wherein each of the at least one first target word line voltage is different from each of the at least one second target word line voltage.

8. The method of claim 6, wherein a total number of the at least one first target word line voltage is different from a total number of the at least one second target word line voltage.

9. The method of claim 6, wherein the at least one first target word line voltage includes a single word line voltage only.

10. The method of claim 6, wherein the at least one second target word line voltage includes at most 2^{(N-1)} word line voltages, where N is a total number of the plurality of bits stored in each of the multi-level non-volatile memory cells.

11. The method of claim 6, wherein the plurality of first target bits belong to more frequently accessed data, and the plurality of second target bits belong to less frequently accessed data.

12. The method of claim 6, wherein the non-volatile memory cell is a NOR flash or a NAND flash.
